(19) United States
(12) Patent Application Publication
(10) Pub. No.: US 2011/0057672 A1
(43) Pub. Date: Mar. 10, 2011

(54) COAXIAL SENSOR FOR TIME-DOMAIN REFLECTOMETRY

(75) Inventor: Whitney Skaling, Buellton, CA (US)

(73) Assignee: Soilmoisture Equipment Corp., Goleta, CA (US)

(21) Appl. No.: 12/557,439

(22) Filed: Sep. 10, 2009

(51) Int. Cl. G01R 27/08

(52) U.S. Cl. 324/694; 324/693

(57) ABSTRACT

A sensor is provided for testing a porous medium using time-domain reflectometry. The sensor includes an inner conductor, an outer conductor and a ceramic material interposed there-between. The inner conductor runs along a longitudinal axis of the sensor. The outer conductor has a hollow axial interior and is oriented around the inner conductor. The ceramic material is solid, porous, exhibits a known liquid release curve and fills an axial gap between the inner and outer conductors. A dielectric substance can be applied to an exterior surface of the inner conductor to enable the testing of a porous medium which is highly dissipative. The inner conductor can be permeable and have a hollow axial interior. A hydrophobic material can also be interposed between the inner and outer conductors.

### BACKGROUND

Time-domain reflectometry (TDR) is a measurement technique which is used to test a medium of interest, determine various properties of the medium, and optionally monitor the medium on an ongoing basis to automatically detect changes in its properties. A TDR system generally includes a probe or sensor which is disposed in the medium being tested. The design and configuration of the probe/sensor are typically adapted to the specific type of medium being tested and the specific type(s) of medium properties being determined. TDR is used in a diverse set of applications to test a wide range of different types of media. For example, TDR is used to locate defects and discontinuities in electrical cables, electrical connectors, printed circuit boards (PCBs), integrated circuit packages, optical fibers and optical connectors. TDR is also used to determine fluid levels and mixing ratios of liquid dielectrics in a variety of industrial, geotechnical and hydrology applications. TDR is also used to determine slope movement in a variety of geotechnical applications.

### SUMMARY

This Summary is provided to introduce a selection of concepts, in a simplified form, that are further described hereafter in the Detailed Description. This Summary is not intended to identify key features or essential features of the claimed subject matter, nor is it intended to be used as an aid in determining the scope of the claimed subject matter.

Coaxial sensor embodiments described herein generally involve a sensor for testing a porous medium using time-domain reflectometry. In one exemplary embodiment the sensor includes an inner conductor, an outer conductor and a ceramic material which is interposed between the inner and outer conductors. The inner conductor runs along a longitudinal axis of the sensor. The outer conductor has a hollow axial interior and is oriented around the inner conductor such that an axial gap exists between the inner and outer conductors. The ceramic material is solid, porous, exhibits a known liquid release curve and fills the axial gap between the inner and outer conductors. In another exemplary embodiment a dielectric substance can be applied to an exterior surface of the inner conductor, where this dielectric substance has a prescribed thickness and enables the testing of a porous medium which is highly dissipative. In yet another exemplary embodiment the inner conductor can be permeable and have a hollow axial interior. In yet another exemplary embodiment a hydrophobic material can be interposed between the inner and outer conductors.

### DESCRIPTION OF THE DRAWINGS

The specific features, aspects, and advantages of the coaxial sensor embodiments described herein will become better understood with regard to the following description, appended claims, and accompanying drawings where:

FIG. 1 is a diagram illustrating an exemplary embodiment, in simplified form, of a system for implementing the coaxial sensor embodiments described herein.

FIG. 2 is a diagram illustrating a longitudinal perspective view, in simplified form, of one embodiment of the coaxial sensor.

FIG. 3 is a diagram illustrating a top view, in simplified form, of the coaxial sensor of FIG. 2.

FIG. 4 is a diagram illustrating a longitudinal cross-sectional view, in simplified form, of the coaxial sensor of FIG. 2 taken along line A-A of FIG. 3.

FIG. 5 is a diagram illustrating a longitudinal cross-sectional view, in simplified form, of an another embodiment of the coaxial sensor taken along line A-A of FIG. 3 where the sensor has a hollow axial interior.

### DETAILED DESCRIPTION

In the following description of coaxial sensor embodiments reference is made to the accompanying drawings which form a part hereof, and in which are shown, by way of illustration, specific embodiments in which the coaxial sensor can be practiced. It is understood that other embodiments can be utilized and structural changes can be made without departing from the scope of the coaxial sensor embodiments.

### 1.0 Coaxial Sensor for Time-Domain Reflectometry (TDR)

Generally speaking, the coaxial sensor embodiments described herein are applicable to testing a porous medium, where the testing can measure one or more dielectric influences in the medium and/or one or more characteristics of the medium. Exemplary dielectric influences in the medium which can be measured include the volumetric liquid content of the medium and the salinity (i.e., salt content) of the medium, among other things. Exemplary characteristics of the medium which can be measured include the viscosity of the medium, the fluid holding capabilities of the medium, and other detectable physical or chemical properties of the medium.

The coaxial sensor embodiments described herein are advantageous for a variety of reasons including, but not limited to, the following. Very precise measurements of the dielectric influences in the medium can be made even when the medium has a very small content of the dielectric influences. The measurements can be made and then analyzed very quickly. The measurements can be made and analyzed either once at a particular point in time, or on an ongoing basis over a period of time using automation. Thus, the medium can be continually monitored and any changes in its properties can be automatically detected.

Furthermore, a wide variety of different types of porous media and liquids can be tested. Exemplary types of porous media that can be tested include soil (which may include materials such as clay, sediments and organic matter), wood, rock, concrete, slurries of various sorts, foodstuffs, and grains, among other things. The media can be tested in situ (e.g., one or more sensors can be disposed at different locations in a farm field, process facility, or the like) or a sample of the media can be taken (such as a core sample and the like) and subsequently tested in a different setting such as a laboratory environment or the like.

### 1.1 System Environment

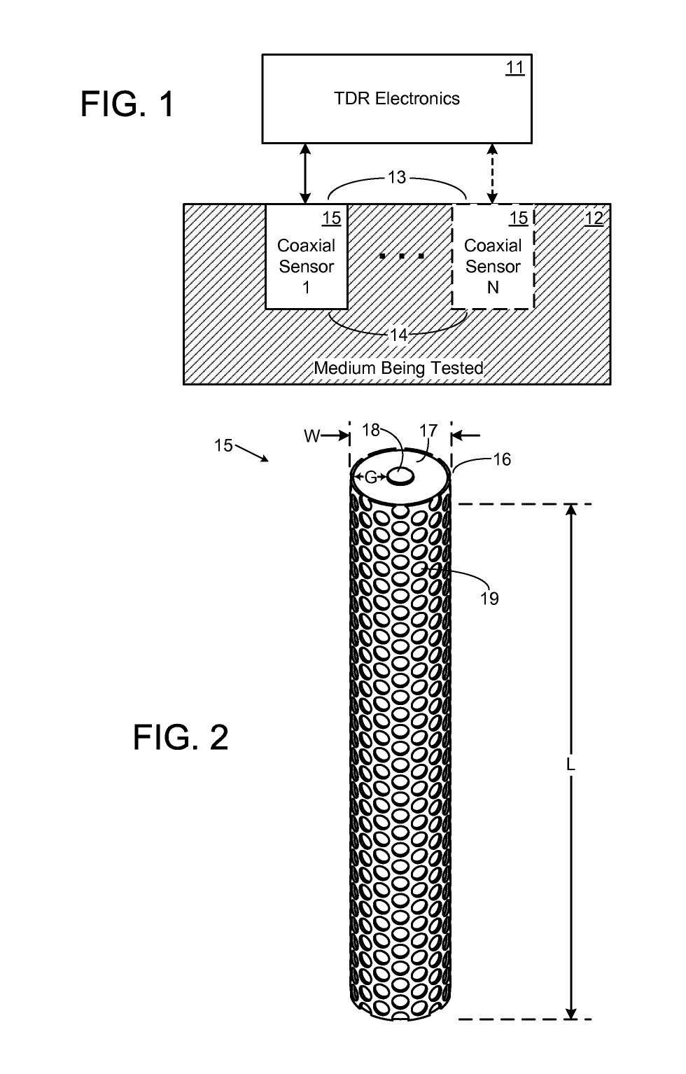

FIG. 1 illustrates an exemplary embodiment, in simplified form, of a suitable system environment in which the coaxial sensor embodiments described herein can be implemented. The environment illustrated in FIG. 1 is only one example of a suitable system environment and is not intended to suggest any limitation as to the scope of use or functionality of the coaxial sensor embodiments. Neither should the system environment be interpreted as having any dependency or requirement relating to any one or combination of the components discussed hereafter in this section.

As exemplified in FIG. 1, a suitable system environment for implementing the coaxial sensor embodiments described herein generally includes the following components. One or more coaxial sensors 15 are disposed within a porous medium which is being tested 12. In the situation where a plurality of sensors 15 are used, each sensor could be disposed at a different location within the medium 12 so as to provide an analysis of the medium which covers a larger vertical and/or horizontal area. Time-domain reflectometry (TDR) electronics 11 are electrically connected to the proximal end 13 of each of the sensors 15. The TDR electronics 11 interoperate with each sensor 15 individually to test the medium 12. Generally speaking, the TDR electronics 11 include a signal generator module (not shown), a signal detector module (not shown) and a signal processor module (not shown) whose operation will be described in more detail hereafter. In the situation where a plurality of sensors 15 are used, the TDR electronics 11 also include a signal multiplexer module (not shown) which generally allows the signal generator, signal detector and signal processor modules to be time-shared amongst each of the sensors.

Referring again to FIG. 1, the TDR electronics 11 interoperate with each coaxial sensor 15 individually in a time-shared manner as follows. The signal generator module transmits an original short rise-time, short duration electrical pulse into the proximal end 13 of the sensor 15 and into the signal processor module, which records the transmitted original pulse. Generally speaking, the sensor 15 operates as a transmission line (also known as a “wave guide”) and provides a means for the original electrical pulse and a resulting reflected electrical pulse to propagate along the sensor as follows. The original electrical pulse propagates from the proximal end 13 of the sensor 15 toward the distal end 14 of the sensor. The distal end 14 of the sensor 15 is un-terminated so that when the original pulse reaches the distal end of the sensor the original pulse is reflected, thus generating the reflected electrical pulse which propagates from the distal end of the sensor back toward the proximal end 13 of the sensor. When the reflected pulse reaches the proximal end 13 of the sensor 15 the reflected pulse is received by the signal detector module. The signal detector module then passes the received reflected pulse to the signal processor module which records the received reflected pulse. Generally speaking and as will be described in more detail hereafter, the signal processor module can then analyze the received reflected pulse and compare it to the transmitted original pulse in a variety of different ways in order to compute a current measurement of one or more dielectric influences in the medium 12, or a current measurement of one or more characteristics of the medium.

### 1.2 Coaxial Sensor

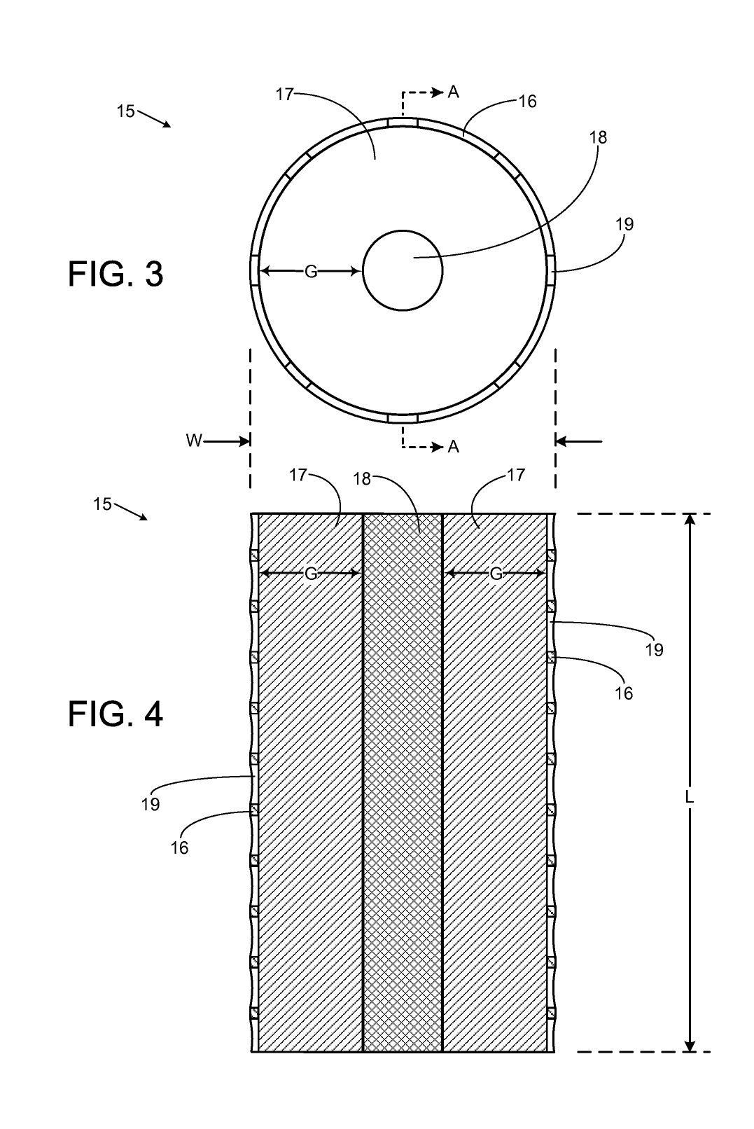

FIGS. 2-4 illustrate one embodiment, in simplified form, of the aforementioned coaxial sensor. More particularly, FIG. 2 illustrates a longitudinal perspective view of one embodiment of the coaxial sensor. FIG. 3 illustrates a top view of the sensor of FIG. 2. FIG. 4 illustrates a longitudinal cross-sectional view of the sensor of FIG. 2 taken along line A-A of FIG. 3. Generally speaking and as exemplified in FIGS. 2-4, the sensor 15 includes an inner conductor 18, a hollow and permeable outer conductor 16, and a solid and porous ceramic material 17 which is interposed between the inner and outer conductors. More particularly, the inner conductor 18 runs along the longitudinal axis of the sensor 15. The outer conductor 16 has a hollow axial interior and is oriented around the inner conductor 18 such that an axial gap G exists between the inner and outer conductors. The outer conductor 16 is perforated with a plurality of openings 19 which are uniformly distributed along the outer conductor, thus making it permeable. The ceramic material 17 serves as a dielectric between the outer and inner conductors 16 and 18. In other words, the ceramic material provides a means for preventing the inner conductor 18 from coming into direct electrical contact with the outer conductor 16.

As exemplified in FIGS. 2-4, the outer conductor 16 and the inner conductor 18 can share a common longitudinal length L, and the solid and porous ceramic material 17 can fill the gap G between the outer and inner conductors 16 and 18 along their entire length L. Alternate embodiments of the coaxial sensor (not shown) are also possible where the outer conductor has a first longitudinal length L1, the inner conductor has a second longitudinal length L2, the outer and inner conductors are longitudinally aligned at the proximal end of the sensor, and L1 and L2 are different such that at the distal end of the sensor either the outer conductor longitudinally extends beyond the inner conductor or vice versa. More particularly, in one alternate embodiment of the sensor the longitudinal length L1 of the outer conductor can be greater than the longitudinal length L2 of the inner conductor, and the ceramic material can fill the gap between the outer and inner conductors along the length L2 and then extend beyond the distal end of the inner conductor up to the distal end of the outer conductor (i.e., the ceramic material has a longitudinal length equal to L1). In another alternate embodiment of the sensor the longitudinal length L1 of the outer conductor can be less than the longitudinal length L2 of the inner conductor, and the ceramic material can fill the gap between the outer and inner conductors along the length L1 and then extend beyond the distal end of the outer conductor up to the distal end of the inner conductor (i.e., the ceramic material has a longitudinal length equal to L2).

Referring again to FIGS. 2-4, the openings 19 in the hollow and permeable outer conductor 16 allow the solid and porous ceramic material 17 to maintain fluid contact with the medium being tested. This allows for a fast equalization of the liquid content within the medium being tested and the liquid content within the ceramic material 17, and also allows this equalization to be continuously maintained as the liquid content within the medium changes. In other words, when a previously unused sensor 15 (i.e., a sensor whose ceramic material is dry) is disposed in the medium for the first time, any liquid which is present in the medium will flow from the medium, through the openings 19, and be absorbed into the ceramic material 17 until the liquid content within the medium and that within the ceramic material are equalized. Then, if the liquid content of the medium increases additional liquid will flow from the medium, through the openings 19, and be absorbed into the ceramic material 17 until the liquid content within the medium and that within the ceramic material are re-equalized. Likewise, if the liquid content of the medium decreases, liquid will flow from the ceramic material 17, through the openings 19, and be absorbed back into the medium until the liquid content within the medium and that within the ceramic material are re-equalized. As exemplified in FIGS. 2-4, the ceramic material 17 is also in fluid contact with the medium at both longitudinal ends of the sensor 15. As such, liquid will similarly flow into and out of the ceramic material 17 through both longitudinal ends of the sensor.

Referring again to FIGS. 2-4, the inner conductor 18 and the hollow and permeable outer conductor 16 can be constructed from any material which is electrically conductive. By way of example but not limitation, the inner and outer conductors can be constructed from a variety of different metals such as copper, brass, stainless steel, nickel alloys, aluminum, gold, platinum, silver, and the like. The inner and outer conductors can also be constructed by sintering a powdered form of these metals. The inner and outer conductors can also be formed as a composite material using vapor deposition, liquid deposition, or flame deposition of any of these metals on top of a non-conductive material. The inner and outer conductors can either be constructed from the same material, or they can be constructed from different materials.

In the coaxial sensor embodiment exemplified in FIGS. 2-4, the inner conductor 18 is linear, it has an axial interior that is solid, and it has a radial cross-sectional shape that is circular. A variety of alternate embodiments of the inner conductor (not shown) are also possible. By way of example but not limitation, rather than having an axial interior that is solid, the inner conductor can also have an axial interior that is hollow. Furthermore, regardless of whether the axial interior of the inner conductor is solid or hollow, rather than having a radial cross-sectional shape that is circular the inner conductor can also have any other radial cross-sectional shape. Thus, the inner conductor can have a radial cross-sectional shape that is oval, triangular, square, rectangular, pentagonal, hexagonal or octagonal, among others. Additionally, rather than being linear, the inner conductor can also be helical. Forming the inner conductor as a helix serves to increase the effective length of the inner conductor, and thus serves to increase the time it takes for the aforementioned original and reflected electrical pulses to propagate along the sensor as described heretofore. This can serve to further increase the sensor's measurement precision and its ability to measure low concentrations of liquids.

In the coaxial sensor embodiment exemplified in FIGS. 2-4 the hollow and permeable outer conductor 16 has a radial cross-sectional shape that is circular, and it is uniformly perforated with a plurality of openings 19 each of which have a circular shape. A variety of alternate embodiments of the outer conductor (not shown) are also possible. By way of example but not limitation, rather than having a radial cross-sectional shape that is circular, the outer conductor can also have any other radial cross-sectional shape. Thus, the outer conductor can have a radial cross-sectional shape that is oval, triangular, square, rectangular, pentagonal, hexagonal or octagonal, among others. Furthermore, rather than each of the openings having a circular shape, each of the openings can have any other two dimensional shape. Thus, each of the openings can have a triangular shape, a square shape, a rectangular shape or a hexagonal shape, among others. A mixture of two or more different shapes can also be employed for the openings. Yet furthermore, the outer conductor can also be helical, or it can be formed as a mesh.

In the coaxial sensor embodiment exemplified in FIGS. 2-4 the inner conductor 18 and the outer conductor 16 have the same radial cross-sectional shape (i.e., both have a radial cross-sectional shape that is circular). It is noted that a variety of alternate embodiments of the coaxial sensor (not shown) are also possible where the radial cross-sectional shape of the inner conductor is different than the radial cross-sectional shape of the outer conductor. By way of example but not limitation, the radial cross-sectional shape of the inner conductor can be round and that of the outer conductor can be square, or vice versa. The radial cross-sectional shape of the inner conductor can be oval and that of the outer conductor can be rectangular, or vice versa. The radial cross-sectional shape of the inner conductor can be triangular and that of the outer conductor can be octagonal, or vice versa. The inner conductor can also be formed as a helix and the outer conductor can have a radial cross-sectional shape which square, or vice versa.

Referring again to FIGS. 2-4, the radial cross-sectional width W of the coaxial sensor 15, the axial gap G within the sensor, and the longitudinal length L of the sensor can have a variety of different sizes. Generally speaking, the size of the width W, gap G and length L for a given sensor can be tailored to factors such as the particular type of porous medium being tested, the particular dielectric influences in the medium and/or characteristics of the medium which are being measured, and the particular manner in which the testing is performed (e.g., whether the medium is being tested in situ or a sample of the medium is being tested in a different setting such as a laboratory environment or the like). By way of example but not limitation, in the situation where a medium such as soil is being tested in situ, the inner conductor 18 of the sensor 15 has an axial interior that is solid and radial cross-sectional shape that is circular, and the hollow and permeable outer conductor 16 of the sensor has a radial cross-sectional shape that is circular, the sensor may have a gap G of 5/16 of an inch, a width W of one inch and a length L of five inches. In the situation where a soil core sample is being tested in a laboratory environment, the inner conductor 18 of the sensor 15 has an axial interior that is solid and radial cross-sectional shape that is circular, and the hollow and permeable outer conductor 16 of the sensor has a radial cross-sectional shape that is circular, the sensor may have a gap G of 5/64 of an inch, a width W of ¼ of an inch and a length L of 1.25 inches. Such a “miniaturized” version of the sensor is advantageous since it can be used to make measurements at different locations in the sample without significantly disturbing the sample.

Referring again to FIGS. 2-4, the solid and porous ceramic material 17 has a continuous, interconnected system of pores (not shown) which is permeable to liquids, gasses and various combinations thereof. The ceramic material exhibits a known liquid-release curve (also known in the arts of hydrology and soil science as a “moisture-release curve” or a “moisture-retention curve”) due to the fact that the pores have a known distribution throughout the ceramic material, and the fact that the pores have a known size distribution. As is appreciated in the hydrology and soil science arts, the liquid-release curve of a material defines the relationship between the liquid content and the matric liquid potential of the material. As the liquid content varies within the ceramic material the dielectric nature of the ceramic material will change. In other words, the ratio of liquid to air within the pores of the ceramic material generally determines the dielectric characteristics of the ceramic material.

Using the ceramic material as a variable dielectric in the coaxial sensor embodiments described herein is advantageous for a variety of reasons, including but not limited to the following. The ceramic material is naturally hydrophilic. Thus, a polar liquid from the surrounding medium being tested is “wicked” into the pores of the ceramic material by capillary action. In other words, the liquid is naturally pulled from the medium and flows into the pores of the ceramic material (or is pulled from the pores of the ceramic material and flows back into the medium as the case may be) until the aforementioned equalization is achieved. The ceramic material can be mass produced with very consistent and uniform pore structures throughout the material thus making the aforementioned precise measurements possible. The ceramic material is very durable and generally inert. Thus, the ceramic material will not degrade or change its porosity properties when salt or other minerals or chemicals are present in the medium.

Referring again to FIGS. 2-4, in one embodiment of the coaxial sensor 15 described herein the aforementioned original electrical pulse can be transmitted into the proximal end of the inner conductor 18, and the outer conductor 16 can serve as a means for providing an electrical return path for the original pulse and the aforementioned reflected electrical pulse. In another embodiment of the coaxial sensor the original pulse can be transmitted into the proximal end of the outer conductor and the inner conductor can serve as a means for providing the electrical return path. In either case, the original pulse generates a first electromagnetic (EM) energy wave which propagates along the sensor toward its distal end in conjunction with the original pulse as described heretofore. The reflected pulse generates a second EM energy wave which propagates along the sensor back toward its proximal end in conjunction with the reflected pulse as described heretofore. The first and second EM energy waves have both an electric field component and a magnetic field component which propagate across the gap G between the inner and outer conductors.

As is appreciated in the art of electromagnetism, the relative permittivity (also known as the dielectric constant) of a material specifies a measure of the material's ability to transmit (i.e., “permit”) an electric field. For example, the relative permittivity of air at room temperature (e.g., 70 degrees F.) is approximately one. The relative permittivity of water at room temperature is approximately 80. Referring again to FIGS. 2-4, when the porous ceramic material 17 is dry (i.e., before any liquid has flowed into it) it has a relative permittivity of between four and seven which is generally much less than that of the liquid such as water and the like that the coaxial sensor may be used to measure. Generally speaking, the relative permittivity of the ceramic material changes in conjunction with changes in the amount of liquid which is present within the ceramic material. More particularly, as liquid flows from the medium being tested into the pores of the ceramic material, the relative permittivity of the ceramic material increases. Correspondingly, as liquid flows from the ceramic material back into the medium, the relative permittivity of the ceramic material decreases. These changes in the relative permittivity of the ceramic material affect the original and reflected electrical pulses as follows.

As is appreciated in the art of TDR, as the liquid content of the solid and porous ceramic material increases the velocity of the original electrical pulse as it propagates along the sensor toward its distal end decreases, and the velocity of the reflected electrical pulse as it propagates along the sensor back toward its proximal end similarly decreases. Correspondingly, as the liquid content of the ceramic material decreases the velocity of the original pulse as it propagates along the sensor toward its distal end increases, and the velocity of the reflected pulse as it propagates along the sensor back toward its proximal end similarly increases. The elapsed time between when the original pulse is transmitted into the proximal end of the sensor and when the reflected pulse is received at the proximal end of the sensor is referred to hereafter as a “pulse phase delay.” In one embodiment of the system environment described heretofore the aforementioned signal processor module can determine the current volumetric liquid content of the medium being tested by computing the pulse phase delay, where the liquid content is inferred from the size of this delay. In the case where the volumetric ratio of the liquid within the ceramic material remains constant, other physical parameters of the medium may be determined such as the temperature of medium, mixing ratios of various substances in the medium, and the like.

Generally speaking and as is appreciated in the arts of hydrology and soil science, any salt which is present in the medium being tested will naturally be absorbed into a liquid which is present in the medium. Thus, as the salinity of the medium increases the salinity of the liquid within the ceramic material will increase until equalization occurs there-between. Correspondingly, as the salinity of the medium decreases the salinity of the liquid within the ceramic material will decrease until equalization occurs there-between. As the salinity of the liquid within the ceramic material increases, the impedance of the coaxial sensor generally decreases. Although the aforementioned pulse phase delay is little affected by this impedance decrease, the impedance decrease attenuates the amplitude of the reflected pulse which is received at the proximal end of the coaxial sensor embodiments described herein. The difference between the amplitude of the original electrical pulse which is transmitted into the proximal end of the sensor and the amplitude of the reflected electrical pulse which is received at the proximal end of the sensor is referred to hereafter as a “pulse amplitude difference.” In another embodiment of the system environment, the signal processor module can determine the current salinity of the medium being tested by computing the pulse amplitude difference, where the salinity of the medium is inferred from the size of this difference.

When the medium under test is highly dissipative (such as a medium having a liquid present therein and a high salinity), the amplitude of the reflected electrical pulse can be attenuated and noise can be introduced into the reflected pulse to a degree which can hamper the precision of the measurements being made in the medium. Alternate embodiments of the coaxial sensor described herein are possible where a dielectric substance having a prescribed thickness is applied to the exterior surface of the inner conductor, where the dielectric substance provides a means for allowing the sensor to make precise measurements when the medium is highly dissipative. Exemplary materials which can be used for the dielectric substance include, but are not limited to, nylon, polyethylene, polyvinyl chloride, and the like. In one embodiment of the sensor the dielectric substance can be applied in the form of a coating on the exterior surface of the inner conductor. In another embodiment of the sensor the dielectric substance can be applied in the form of a sleeve which is snugly slipped over the exterior surface of the inner conductor.

It is noted that the following considerations exist when selecting the particular thickness of the dielectric substance that is used. Increasing the thickness of the dielectric substance will reduce the attenuation of the reflected pulse's amplitude and reduce the noise introduced into the reflected pulse, which will generally enhance the precision of the measurements being made in a medium having a high salinity. However, increasing the thickness of the dielectric substance will also reduce the pulse phase delay, which can degrade the precision of the measurements. In an exemplary embodiment of the coaxial sensor described herein a thickness of 10/1000 of an inch is employed for the dielectric substance, which provides a practical balance of these considerations.

### 1.3 Hollow Coaxial Sensor

The coaxial sensor embodiments described heretofore are applicable to testing a porous medium where one or more sensors are disposed within the medium (i.e., the medium being tested surrounds the exterior of the sensors). This section describes additional embodiments of the coaxial sensor which are generally applicable to testing a porous medium where a sample of the medium being tested (such as a soil core sample, a rock core sample, and the like) is snugly placed inside a cavity which is located along the axial interior of the sensor's inner conductor.

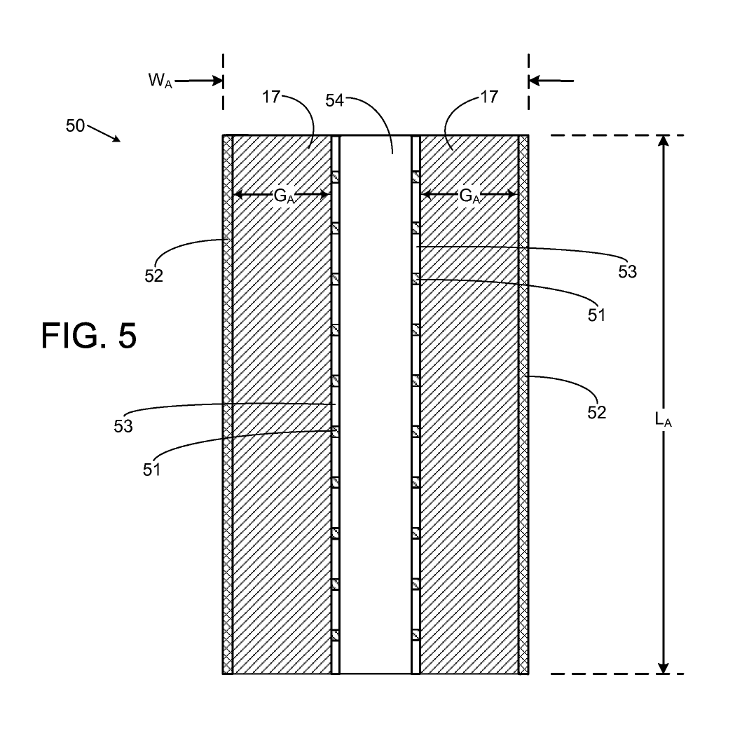

FIG. 5 illustrates a longitudinal cross-sectional view, in simplified form, of another embodiment of the coaxial sensor taken along line A-A of FIG. 3 where the sensor has a hollow axial interior. This embodiment is referred to hereafter as a “hollow coaxial sensor” embodiment. Generally speaking and as exemplified in FIG. 5, the hollow coaxial sensor 50 includes a hollow and permeable inner conductor 51, a hollow and non-permeable outer conductor 52, and the aforementioned solid and porous ceramic material 17 which is interposed between the inner and outer conductors. More particularly, the inner conductor 51 runs along the longitudinal axis of the sensor 50. The inner conductor 51 has a hollow axial interior 54 and is perforated with a plurality of openings 53 which are uniformly distributed along the inner conductor, thus making it permeable. The outer conductor 52 also has a hollow axial interior and is oriented around the inner conductor 51 such that an axial gap GA exists between the inner and outer conductors. As described heretofore, the ceramic material 17 serves as a dielectric between the outer and inner conductors 52 and 51.

Referring again to FIG. 5, a sample of the medium being tested (not shown) is snugly placed inside the hollow axial interior 54 of the inner conductor 51. The radial cross-sectional width W_{A} of the sensor 50, the axial gap G_{A} within the sensor, and the longitudinal length L_{A} of the sensor can have a variety of different sizes. By way of example but not limitation, the sensor 50 may have a width W_{A} of three inches, a gap G_{A} of 5/16 of an inch and a length L_{A} of three inches. It is noted that in addition to the embodiment of the hollow coaxial sensor that has just been described, all of the other material-related and structure-related embodiments described herein for the inner and outer conductors, and all of the various embodiments described herein for the material that is interposed between the inner and outer conductors, also apply to the hollow coaxial sensor.

### 2.0 Additional Embodiments

While the coaxial sensor has been described in more detail by specific reference to embodiments thereof, it is understood that variations and modifications thereof can be made without departing from the true spirit and scope of the coaxial sensor. By way of example but not limitation, rather than implementing the coaxial sensor embodiments described herein in a system environment which employs TDR electronics that include a signal processor module which analyzes the received reflected pulse in the time-domain as described heretofore, an alternate embodiment of the coaxial sensor is possible where the system environment employs a different type of electronics that include a signal processor module which analyzes the received reflected pulse in the frequency-domain.

Additionally, rather than interposing a solid and porous ceramic material which is hydrophilic between the inner and outer conductors as described heretofore, alternate embodiments of the coaxial sensor described herein are also possible where other types of solid and porous materials which are hydrophobic, and which exhibit a known liquid-release curve, can be interposed between the inner and outer conductors. By way of example, but not limitation, the hydrophobic material that is interposed between the inner and outer conductors can be a solid and porous polymer plastic material, or it can be a solid and porous ceramic material which has been treated to be hydrophobic. The use of these hydrophobic materials is advantageous since it allows the coaxial sensor embodiments to work with both polar and non-polar liquids and determine specific dielectric characteristics for these liquids in different physical environments such as different pressures, different temperatures, different mixing ratios, and the like.

It is noted that any or all of the aforementioned embodiments can be used in any combination desired to form additional hybrid embodiments. Although the coaxial sensor embodiments have been described in language specific to structural features and/or methodological acts, it is to be understood that the subject matter defined in the appended claims is not necessarily limited to the specific features or acts described heretofore. Rather, the specific features and acts described heretofore are disclosed as example forms of implementing the claims.

Wherefore, what is claimed is:

1. A coaxial sensor for testing a porous medium using time-domain reflectometry, comprising:
an inner conductor which runs along a longitudinal axis of the sensor;
an outer conductor which is permeable and comprises a hollow axial interior, wherein the outer conductor is oriented around the inner conductor such that an axial gap exists between the inner and outer conductors; and
a ceramic material which is interposed between the inner and outer conductors and fills the axial gap there-between, wherein the ceramic material is solid, porous and exhibits a known liquid release curve.

2. The coaxial sensor of claim 1, wherein,
the inner conductor is constructed from a first material comprising either copper, or brass, or stainless steel, or nickel alloy, or aluminum, or gold, or platinum, or silver, and
the outer conductor is constructed from a second material comprising either copper, or brass, or stainless steel, or nickel alloy, or aluminum, or gold, or platinum, or silver.

3. The coaxial sensor of claim 2, wherein the first material is the same as the second material.

4. The coaxial sensor of claim 2, wherein the first material is different than the second material.

5. The coaxial sensor of claim 1, wherein the inner conductor is linear.

6. The coaxial sensor of claim 5, wherein the inner conductor further comprises:
a solid axial interior; and
a radial cross-sectional shape comprising one of a circular shape, or an oval shape, or a triangular shape, or a square shape, or a rectangular shape, or a pentagonal shape, or a hexagonal shape, or an octagonal shape.

7. The coaxial sensor of claim 5, wherein the inner conductor further comprises:
a hollow axial interior; and
a radial cross-sectional shape comprising one of a circular shape, or an oval shape, or a triangular shape, or a square shape, or a rectangular shape, or a pentagonal shape, or a hexagonal shape, or an octagonal shape.

8. The coaxial sensor of claim 1, wherein the inner conductor is helical.

9. The coaxial sensor of claim 1, wherein the outer conductor further comprises a radial cross-sectional shape comprising one of:
a circular shape; or
an oval shape; or
a triangular shape; or
a square shape; or
a rectangular shape; or
a pentagonal shape; or
a hexagonal shape; or
an octagonal shape.

10. The coaxial sensor of claim 1, wherein,
the outer conductor is perforated with a plurality of openings which are uniformly distributed along the outer conductor, and
said openings allow the ceramic material to maintain fluid contact with the medium being tested.

11. The coaxial sensor of claim 1, wherein the inner conductor and outer conductor comprise a common longitudinal length and the ceramic material extends along the entire longitudinal length.

12. The coaxial sensor of claim 1, wherein the outer conductor comprises a first longitudinal length L1, the inner conductor comprises a second longitudinal length L2, and the outer and inner conductors are longitudinally aligned at a proximal end of the sensor, wherein either,
length L1 is greater than length L2 and the ceramic material extends along the entire length L1, or
length L1 is less than length L2 and the ceramic material extends along the entire length L2.

13. The coaxial sensor of claim 1, wherein either,
the outer conductor is helical, or
the outer conductor is formed as a mesh.

14. The coaxial sensor of claim 1, wherein,
the inner conductor comprises a first radial cross-sectional shape,
the outer conductor comprises a second radial cross-sectional shape, and
the first radial cross-sectional shape is the same as the second radial cross-sectional shape.

15. The coaxial sensor of claim 1, wherein,
the inner conductor comprises a first radial cross-sectional shape,
the outer conductor comprises a second radial cross-sectional shape, and
the first radial cross-sectional shape is different than the second radial cross-sectional shape.

16. A coaxial sensor for testing a porous medium using time-domain reflectometry, comprising:
an inner conductive means for propagating an original electrical pulse from a proximal end of the sensor toward a distal end of the sensor, and for propagating a reflected electrical pulse from the distal end of the sensor back toward the proximal end of the sensor;
a permeable outer conductive means oriented around the inner conductive means for providing an electrical return path for the original and reflected electrical pulses; and
a porous and solid ceramic means interposed between the inner conductive means and the outer conductive means for preventing the inner conductive means from coming into direct electrical contact with the outer conductive means, wherein the ceramic means comprises a known liquid release curve and a relative permittivity which changes in conjunction with changes in the amount of liquid which is present within the porous medium.

17. The coaxial sensor of claim 16, further comprising a dielectric substance means which is applied to an exterior surface of the inner conductive means for allowing the sensor to make precise measurements when the medium is highly dissipative.

18. A coaxial sensor for testing a porous medium which is highly dissipative using time-domain reflectometry, comprising:
an inner conductor which runs along a longitudinal axis of the sensor;
a dielectric substance which is applied to an exterior surface of the inner conductor, wherein said substance has a prescribed thickness;
an outer conductor which is permeable and comprises a hollow axial interior, wherein the outer conductor is oriented around the inner conductor such that an axial gap exists between the inner and outer conductors; and
a ceramic material which is interposed between the inner and outer conductors and fills the axial gap there-between, wherein the ceramic material is solid, porous and exhibits a known liquid release curve.

19. The coaxial sensor of claim 18, wherein,
the prescribed thickness is 10/1000 of an inch, and
the dielectric substance comprises either nylon, or polyethylene, or polyvinyl chloride.

20. The coaxial sensor of claim 18, wherein either the dielectric substance is applied in the form of a coating on the exterior surface of the inner conductor, or the dielectric substance is applied in the form of a sleeve which is snugly slipped over the exterior surface of the inner conductor.

21. The coaxial sensor of claim 18, wherein,
the ceramic material comprises a continuous, interconnected system of pores,
the pores have a known distribution throughout the ceramic material, and
the pores have a known size distribution.

22. A coaxial sensor for testing a porous medium using time-domain reflectometry, comprising:
an inner conductor which runs along a longitudinal axis of the sensor, wherein the inner conductor is permeable and comprises a hollow axial interior;
an outer conductor also comprising a hollow axial interior, wherein the outer conductor is oriented around the inner conductor such that an axial gap exists between the inner and outer conductors; and
a ceramic material which is interposed between the inner and outer conductors and fills the axial gap there-between, wherein the ceramic material is solid, porous and exhibits a known liquid release curve.

23. A coaxial sensor for testing a porous medium using time-domain reflectometry, comprising:
an inner conductor which runs along a longitudinal axis of the sensor;
an outer conductor which is permeable and comprises a hollow axial interior, wherein the outer conductor is oriented around the inner conductor such that an axial gap exists between the inner and outer conductors; and
a hydrophobic material which is interposed between the inner and outer conductors and fills the axial gap there-between, wherein the hydrophobic material is solid, porous and exhibits a known liquid release curve.

24. The coaxial sensor of claim 23, wherein the hydrophobic material comprises either a polymer plastic material or a ceramic material which has been treated to be hydrophobic.
